(19) United States
(12) Patent Application Publication
(10) Pub. No.: US 2016/0299190 A1
(43) Pub. Date: Oct. 13, 2016

(54) SEMICONDUCTOR APPARATUS AND TEST METHOD THEREOF

(71) Applicant: SK hynix Inc., Icheon-si Gyeonggi-do (KR)

(72) Inventor: Seok Bo SHIM, Icheon-si Gyeonggi-do (KR)

(21) Appl. No.: 14/743,025

(22) Filed: Jun. 18, 2015

(30) Foreign Application Priority Data
Apr. 10, 2015 (KR) 10-2015-0051057

(51) Int. Cl. G01R 31/3185; G01R 31/3187

(52) U.S. Cl. CPC G01R 31/318513; G01R 31/3187

(57) ABSTRACT

A semiconductor apparatus includes a plurality of through-silicon vias, and a self repair block. The self repair block charges the plurality of through-silicon vias for a preset threshold time so that pass-state through-silicon vias reaches a reference voltage level, make pass/fail decisions according to voltage levels of the plurality of through-silicon vias, and repair a through-silicon via which is in a fail state.

### CROSS-REFERENCES TO RELATED APPLICATION

The present application claims priority under 35 U.S.C. §119(a) to Korean application number 10-2015-0051057 filed on Apr. 10, 2015, in the Korean Intellectual Property Office, which is incorporated herein by reference in its entirety.

### BACKGROUND

1. Technical Field

Various embodiments generally relate to a semiconductor apparatus, and more particularly to a semiconductor apparatus and a test method thereof.

2. Related Art

A three-dimensional integrated circuit packaging is an integrated circuit manufactured by stacking a plurality of semiconductor chips and interconnecting them using through-silicon vias.

Like all other integrated circuits, these three-dimensional integrated circuits need to be tested for manufacturing defects in order to guarantee the signal transmission quality of the through-silicon vias.

The through-silicon via test may be carried out using external test equipments, which measure the signal quality and make pass/fail decisions.

Further, the external test equipments may carry out a repair process, which includes replacing failed through-silicon vias with good ones.

### SUMMARY

Various embodiments are directed to a semiconductor apparatus and a test method thereof capable of self-performing a through via test and repair.

In an embodiment, a semiconductor apparatus may include: a plurality of through vias; and a self repair block configured to charge the plurality of through vias for a preset threshold time such that passed through vias may reach a reference level, judge a pass or a fail according to voltage levels of the plurality of respective charged through vias, and repair a through via judged as a fail.

In an embodiment, a semiconductor apparatus may include: a plurality of stacked semiconductor chips; and a plurality of through vias formed in the plurality of semiconductor chips, and electrically coupled with one another, wherein any one semiconductor chip among the plurality of semiconductor chips performs a charge operation of charging the plurality of through vias for a preset threshold time, such that passed through vias may reach a reference level, and wherein another semiconductor chip among the plurality of semiconductor chips performs a test operation of judging a pass or a fail according to voltage levels of the plurality of respective charged through vias and a repair operation of repairing a through via judged as a fail.

In an embodiment, a method for testing a semiconductor apparatus including a plurality of semiconductor chips which are formed with a plurality of through vias and are stacked may include: a charge action of charging the plurality of through vias for a preset threshold time, by any one among the plurality of stacked semiconductor chips, such that passed through vias may reach a reference level; a test action of judging a pass or a fail of the plurality of through vias by comparing voltage levels of the plurality of through vias and the reference level, by another one among the plurality of stacked semiconductor chips; and a repair action of performing a repair operation for a through via judged as a fail among the plurality of through vias, by another one among the stacked semiconductor chips.

Any one among the plurality of stacked semiconductor chips and another one among the plurality of stacked semiconductor chips may be determined according to position signals which define stack positions of the plurality of stacked semiconductor chips.

The reference level may be the same level as a level of a power supply terminal which is used to charge the plurality of through vias in the charge action.

### BRIEF DESCRIPTION OF THE DRAWINGS

FIG. 1 is a diagram illustrating a configuration example of a semiconductor apparatus 100 in accordance with an embodiment.

FIG. 2 is a diagram illustrating a configuration example of the self repair block 201 shown in FIG. 1.

FIG. 3 is a diagram illustrating a configuration example of the control signal generation unit 210 shown in FIG. 2.

FIG. 4 is an example waveform diagram to assist in the explanation of a method for setting the pulse width of a second control signal P1 shown in FIG. 3.

FIG. 5 is a diagram illustrating a configuration example of the test logic 271 shown in FIG. 2.

### DETAILED DESCRIPTION

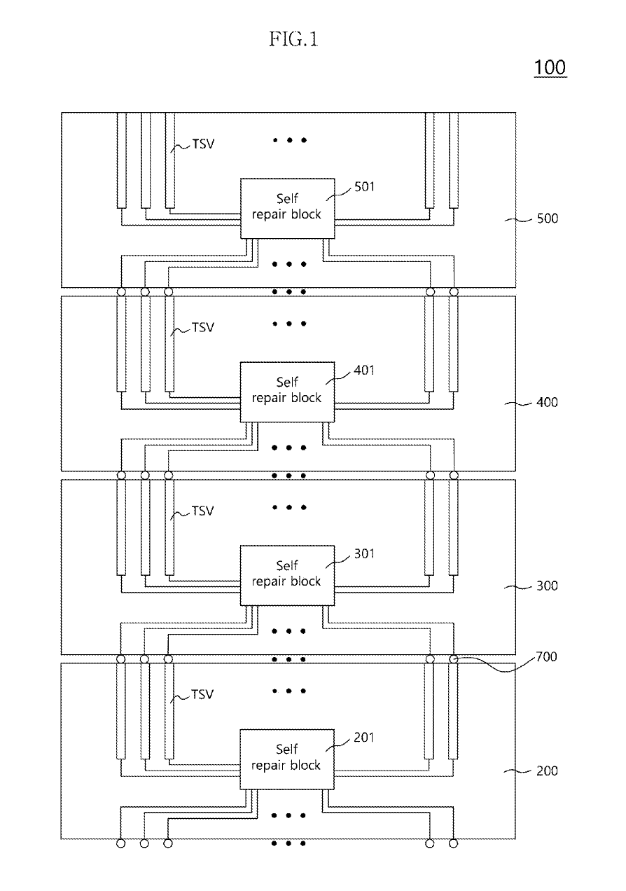

FIG. 1 is a diagram illustrating a configuration example of a semiconductor apparatus 100 in accordance with an embodiment.

As shown in FIG. 1, a semiconductor apparatus 100 may include a plurality of semiconductor chips 200 to 500 which are stacked. For example, the plurality of semiconductor chips 200 to 500 may be vertically stacked on top of each other using through-silicon vias TSV.

Each semiconductor chip 200 to 500 may include therein a plurality of through-silicon vias TSV, and self repair blocks 201 to 501.

A plurality of bumps 700 may electrically connect two adjacent semiconductor chips between the plurality of semiconductor chips 200 to 500, and the plurality of through-silicon vias TSV of a semiconductor chip may be electrically coupled to the plurality of through-silicon vias TSV of another semiconductor chip through the plurality of bumps 700.

In an embodiment, self repair blocks 201 to 501 may charge the plurality of through-silicon vias TSV for a predetermined time, make pass/fail decisions on the basis of the voltage levels of the through-silicon vias TSV, and repair through-silicon vias TSV on which a fail decision has been made.

The plurality of semiconductor chips 200 to 500 may be configured in the same way, and the self repair blocks 201 to 501 may also be configured in the same way.

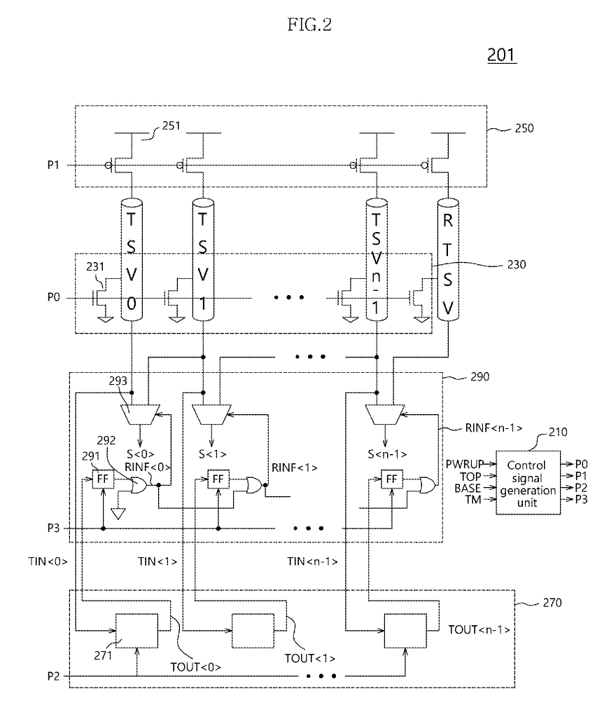

As shown in FIG. 2, the self repair block 201 of the semiconductor chip 200 may include a control signal generation unit 210, a discharge unit 230, a charge unit 250, a test unit 270, and a repair unit 290.

The control signal generation unit 210 may generate a plurality of control signals (e.g., first to fourth control signals P0 to P4) in response to an initial operation signal (e.g., power-up signal PWRUP), a plurality of position signals (e.g., first and second position signals TOP and BASE), and a test mode signal TM of the semiconductor apparatus 100.

The control signal generation unit 210 may sequentially generate the first to fourth control signals P0 to P3 with a predetermined time interval.

The control signal generation unit 210 may change the pulse width of a second control signal P1 according to the test mode signal TM.

The initial operation signal may include a power-up signal PWRUP.

The plurality of position signals may be signals which have information about positions of the plurality of semiconductor chips 200 to 500. For example, a first position signal TOP, which indicates an uppermost chip, may be set to be enabled in the uppermost semiconductor chip 500, and a second position signal BASE, which indicates a lowermost chip, may be set to be enabled in the lowermost semiconductor chip 200.

The discharge unit 230 may discharge a plurality of through-silicon vias TSV0, TSV1, . . . , TSVn-1 and RTSV in response to a first control signal P0.

One of the plurality of through-silicon vias may be used as a redundancy through-silicon via RTSV.

The discharge unit 230 may include a plurality of switching elements (e.g., a plurality of transistors 231) each of which is electrically coupled to each of the plurality of through-silicon vias TSV0, TSV1, . . . , TSVn-1 and RTSV.

The plurality of transistors 231 may have sources coupled to the plurality of through-silicon vias TSV0, TSV1, . . . , TSVn-1 and RTSV, drains coupled to a ground terminal, and gates which receive the first control signal P0.

The charge unit 250 may charge up the plurality of through-silicon vias TSV0, TSV1, . . . , TSVn-1 and RTSV in response to the second control signal P1.

The charge unit 250 may include a plurality of switching elements (e.g., a plurality of transistors 251) each of which is electrically coupled to each of the plurality of through-silicon vias TSV0, TSV1, . . . , TSVn-1 and RTSV.

The plurality of transistors 251 may have sources coupled to a power supply terminal, drains coupled to the plurality of through-silicon vias TSV0, TSV1, . . . , TSVn-1 and RTSV, and gates which receive the second control signal P1.

The test unit 270 may make pass/fail decisions on the basis of voltage signals TIN<0:n-1>, which are transmitted through the plurality of through-silicon vias TSV0, TSV1, . . . and TSVn-1, in response to the third control signal P2, and output a plurality of test result signals TOUT<0:n-1>.

The test unit 270 may compare a plurality of voltage signals TIN<0:n-1> with a reference voltage level in response to the third control signal P2, judge a pass or a fail of the plurality of through-silicon vias TSV0, TSV1, . . . and TSVn-1, and output the plurality of test result signals TOUT<0:n-1>.

The test unit 270 may include a plurality of test logics 271.

The plurality of test logics 271 may compare the plurality of voltage signals TIN<0:n-1> with a reference voltage level in response to the third control signal P2, make pass/fail decisions with respect to the plurality of through-silicon vias TSV0, TSV1, . . . and TSVn-1, and output the plurality of test result signals TOUT<0:n-1>.

For example, a first test logic 271 may compare a first voltage signal TIN<0> with the reference voltage level in response to the third control signal P2, make pass/fail decisions with respect to a first through-silicon via TSV0, and output a first test result signal TOUT<0>.

The repair unit 290 may output a signal selected between two signals outputted from two adjacent through-silicon vias by using a plurality of repair signals RINF<0:n-1> which are generated in response to the fourth control signal P3 and the plurality of test result signals TOUT<0:n-1>, and repair a through-silicon via at which a failure arose.

The repair unit 290 may include a plurality of flip-flops 291, a plurality of logic gates 292, and a plurality of multiplexers 293.

The plurality of flip-flops 291 may store the plurality of test result signals TOUT<0:n-1> in response to the fourth control signal P3.

The plurality of logic gates 292 may perform a logical operation (e.g. “OR” operation) on previous repair signals among the repair signals RINF<0:n-1> and outputs of the plurality of flip-flops 291, and output the repair signals RINF<0:n-1>.

For example, a first logic gate 292 may perform an OR operation on the test result signal TOUT<0>, which is stored by a first flip-flop 291, and a ground voltage level, and generate the repair signal RINF<0>.

Since the first logic gate 292 is associated with the first through-silicon via TSV0, which has no previous repair signal, the first logic gate 292 is inputted with the ground voltage level instead of a previous repair signal.

For another example, logic gates other than the first logic gate 292 may perform an OR operations on the stored test result signals (e.g., TOUT<1>) and the previous repair signals (e.g., RINF<0>), and generate the repair signals (e.g., RINF<1>).

As a result, if any one test result between two test results of adjacent through-silicon vias is a failure, a corresponding signal bit among the plurality of repair signals RINF<0:n-1> may be enabled.

The plurality of multiplexers 293 may select any one of two signals being outputted from two adjacent through-silicon vias according to the plurality of repair signals RINF<0:n-1>, and generate a plurality of output signals S<0:n-1>.

For example, a first multiplexer 293 may select and output any one of two signals being outputted from two adjacent through-silicon vias TSV0 and TSV1 according to the repair signal RINF<0>.

In an embodiment, each of the plurality of multiplexers 293 may have first and second inputs.

For example, each of the plurality of multiplexers 293 may select and output the second input when a corresponding repair signal of the plurality of repair signals RINF<0:n-1> is a logic level (e.g., a logic high level) that indicates a failure of a corresponding through-silicon via.

For example, each of the plurality of multiplexers 293 may select and output the first input when a corresponding repair signal of the plurality of repair signals RINF<0:n-1> is a logic level (e.g., a logic low level) that indicates a pass of a corresponding through-silicon via.

As described above, each of the plurality of repair signals RINF<0:n-1> may be enabled even when any one between two test results of a corresponding through-silicon via and a previous through-silicon via indicates a failure.

For example, when assuming that n=5, the self repair blocks 201 may have first to fifth through-silicon vias TSV0 to TSV4 and a redundancy through-silicon via RTSV. In the case where the second through-silicon via TSV1 out of the first to fifth through-silicon vias TSV0 to TSV4 is found to be a failure, the plurality of repair signals RINF<0:n-1> have the values of ‘01111’.

A repair operation for the second through-silicon via TSV1 may be performed by selecting the first, third, fourth, and fifth through-silicon vias TSV0, TSV2, TSV3, TSV4 and the redundancy through-silicon via RTSV and generating the plurality of output signals S<0:n-1> with the values of ‘01111’ according to the plurality of repair signals RINF<0:n-1>.

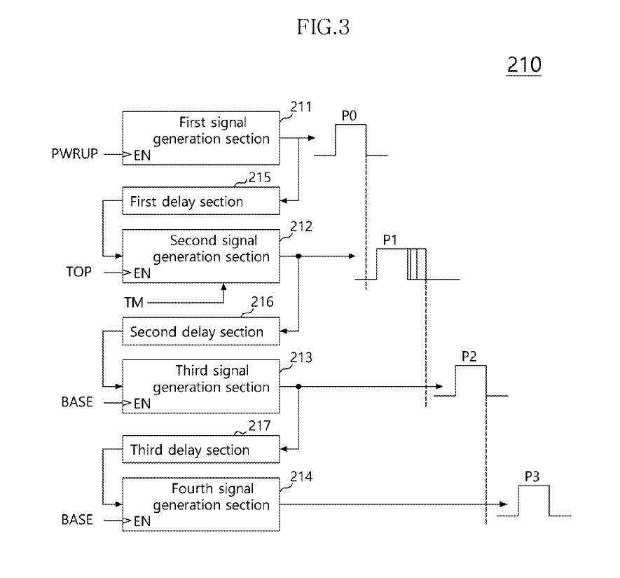

As shown in FIG. 3, the control signal generation unit 210 may include first to fourth signal generation sections 211 to 214 and first to third delay sections 215 to 217.

The first signal generation section 211 may be enabled according to the power-up signal PWRUP, and generate the first control signal P0.

The first delay section 215 may delay the first control signal P0 by a predetermined time, and output the delayed first control signal P0.

The second signal generation section 212 may be enabled according to the first position signal TOP, and generate the second control signal P1 by using the output signal of the first delay section 215.

The second signal generation section 212 may control the pulse width of the second control signal P1 according to the test mode signal TM.

The second delay section 216 may delay the second control signal P1 by a predetermined time, and output the delayed second control signal P1.

The third signal generation section 213 may be enabled according to the second position signal BASE, and generate the third control signal P2 by using the output signal of the second delay section 216.

The third delay section 217 may delay the third control signal P2 by a predetermined time, and output the delayed third control signal P2.

The fourth signal generation section 214 may be enabled according to the second position signal BASE, and generate the fourth control signal P3 by using the output signal of the third delay section 217.

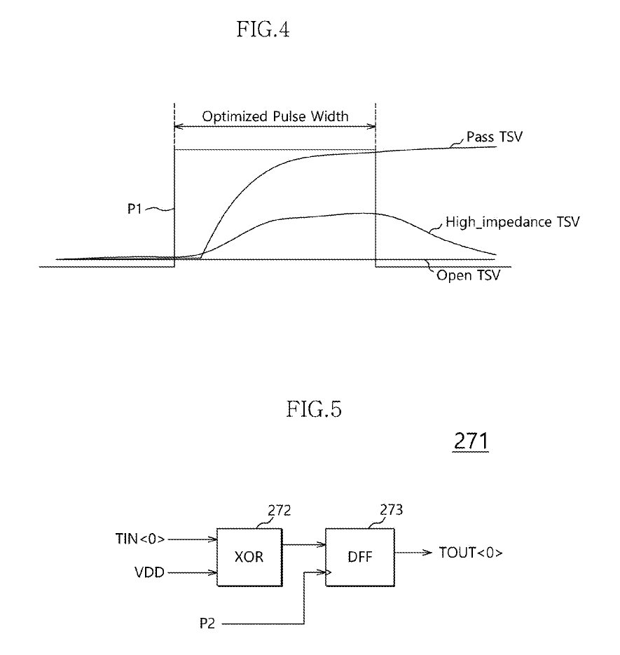

In an embodiment, through-silicon vias may be charged in response to the second control signal P1, and the second control signal P1 may have an optimized pulse width by using the test mode signal TM, which will be described below with reference to FIG. 4.

In an embodiment, the optimized pulse width may be defined as a pulse width corresponding to a threshold time during which a voltage level, which varies according to the amount of charges accumulated in a through-silicon via, reaches a preset voltage level (e.g., a power supply voltage VDD).

As shown in FIG. 4, a through-silicon via may be identified as a pass state, an open state or a high impedance state.

The pass state may mean that the impedance of a through-silicon via is an appropriate level, the open state may mean that a through-silicon via has an infinite impedance, and the high impedance state may mean that the impedance of a through-silicon via exceeds the appropriate level.

Since the open state does not allow charges to be accumulated in a through-silicon via, a voltage level, which varies according to an amount of accumulated charges, may not reach the power supply voltage VDD.

A voltage level of a through-silicon via may reach the power supply voltage VDD if the through-silicon via is in the pass state (hereinafter referred to as a pass-state through-silicon via), and a charge time reaches a specified period of time.

A through-silicon via, which is in the high impedance state, takes more charging time to reach the power supply voltage VDD.

Therefore, if a threshold time during which a voltage level reaches a preset voltage level is calculated by charging a plurality of pass-state through-silicon via samples and measuring voltage levels of them as described above, the pulse width of the second control signal P1 may be optimized on the basis of the calculated threshold time.

As shown in FIG. 5, the test logic 271 may include an XOR gate 272 and a flip-flop 273.

The XOR gate 272 may compare the voltage signal TIN<> with the reference voltage level, for example, the power supply voltage VDD, and output an output.

The flip-flop 273 may store an output of the XOR gate 272 in response to the third control signal P2, and output the test result signal TOUT<0>.

For example, in the case where the through-silicon via TSV0 is in the pass state, the voltage signal TIN<0> may have the same voltage level as the power supply voltage VDD.

Accordingly, the XOR gate 272 may output a low level, and the flip-flop 273 may output the test result signal TOUT<0> of a low level in response to the third control signal P2.

In the case where the through-silicon via TSV0 is in the open state or the high impedance state, the voltage signal TIN<0> may have a low voltage level, which is different from the power supply voltage VDD.

Accordingly, the XOR gate 272 may output a high level, and the flip-flop 273 may output the test result signal TOUT<0> of a high level in response to the third control signal P2.

In this way, the plurality of test logics 271 may make pass/fail decisions with respect to each of the plurality of through-silicon vias TSV0, TSV1, . . . and TSVn-1.

In an embodiment, a test operation of the semiconductor apparatus may be carried out as follows.

First, the plurality of through-silicon vias TSV0, TSV1, . . . and TSVn-1 are discharged.

The plurality of semiconductor chips 200 to 500 may perform a pre-discharge operation by connecting the through-silicon vias TSV0, TSV1, . . . , TSVn-1 and RTSV to ground voltage in response to the first control signal P0.

Next, the uppermost semiconductor chip 500 among the plurality of semiconductor chips 200 to 500 may charge up the plurality of through-silicon vias TSV0, TSV1, . . . , TSVn-1 and RTSV by using the power supply voltage VDD during a high-level period of the second control signal P1 which is set to have the optimized pulse width.

The second control signal P1 is enabled according to the first position signal TOP as described above with reference to FIG. 3.

Therefore, the uppermost semiconductor chip 500 may charge up the through-silicon vias of the semiconductor chips 400, 300 and 200 by using the power supply voltage VDD.

Then, the lowermost semiconductor chip 200 among the plurality of semiconductor chips 200 to 500 may make pass/fail decisions with respect to the plurality of through-silicon vias TSV0, TSV1, . . . and TSVn-1 in response to the third control signal P2.

The third control signal P2 is enabled according to the second position signal BASE as described above with reference to FIG. 3.

Therefore, the lowermost semiconductor chip 200 may compare the plurality of voltage signals TIN<0:n-1> with the power supply voltage VDD in response to the third control signal P2, make pass/fail decisions with respect to the plurality of through-silicon vias TSV0, TSV1, . . . and TSVn-1, and output the plurality of test result signals TOUT<0:n-1>.

Next, the lowermost semiconductor chip 200 may perform the repair operation for a through-silicon via in a fail state in response to the fourth control signal P3.

The fourth control signal P3 is enabled according to the second position signal BASE as described above with reference to FIG. 3.

Therefore, the lowermost semiconductor chip 200 may output a signal selected between two signals outputted from two adjacent through-silicon vias by using the plurality of repair signals RINF<0:n-1> which are generated in response to the fourth control signal P3 and the plurality of test result signals TOUT<0:n-1>, and repair a through-silicon which is in a fail state.

While various embodiments have been described above, it will be understood to those skilled in the art that the embodiments described are examples only. Accordingly, the semiconductor apparatus and the test method thereof described herein should not be limited based on the described embodiments.

What is claimed is:

1. A semiconductor apparatus comprising:
a plurality of through-silicon vias; and
a self repair block configured to charge the plurality of through-silicon vias for a preset threshold time so that pass-state through-silicon vias reaches a reference voltage level, make pass/fail decisions according to voltage levels of the plurality of through-silicon vias, and repair a through-silicon via which is in a fail state.

2. The semiconductor apparatus according to claim 1, wherein the self repair block comprises:
a charge unit configured to charge the plurality of through-silicon vias for the preset threshold time;
a test unit configured to compare the voltage levels of the plurality of through-silicon vias and the reference voltage level, and output a plurality of test result signals; and
a repair unit configured to repair a through-silicon via, which is in a fail state, according to the plurality of test result signals.

3. The semiconductor apparatus according to claim 2, wherein the self repair block further comprises:
a discharge unit configured to discharge the plurality of through-silicon vias.

4. The semiconductor apparatus according to claim 2, wherein the test unit comprises:
a plurality of test logics configured to compare a plurality of voltage signals, which are outputted from the plurality of through-silicon vias, with the reference voltage level, make pass/fail decisions with respect to the plurality of respective through-silicon vias, and output the plurality of test result signals.

5. The semiconductor apparatus according to claim 2, wherein the repair unit is configured to repair a through-silicon via, which is in a fail state, by outputting a signal selected between two adjacent through-silicon vias using the plurality of test result signals.

6. The semiconductor apparatus according to claim 2, wherein the repair unit comprises:
a plurality of flip-flops configured to store the plurality of test result signals;
a plurality of logic gates configured to perform a logical operation on previous repair signals, which are generated using the plurality of test result signals, and outputs of the plurality of flip-flops, and output the plurality of repair signals; and
a plurality of multiplexers each configured to select any one of two signals being outputted from two adjacent through-silicon vias according to a corresponding repair signal.

7. A semiconductor apparatus comprising:
a plurality of stacked semiconductor chips; and
a plurality of through-silicon vias formed in the plurality of semiconductor chips, and electrically connecting the plurality of semiconductor chips to one another,
wherein a first semiconductor chip among the plurality of semiconductor chips performs a charging operation to charge up the plurality of through-silicon vias for a preset threshold time so that pass-state through-silicon vias reaches a reference level, and
wherein a second semiconductor chip among the plurality of semiconductor chips performs a test operation to make pass/fail decisions with respect to the plurality of through-silicon vias according to voltage levels of the plurality of through-silicon vias and performs a repair operation with respect to a through-silicon via which is in a fail state.

8. The semiconductor apparatus according to claim 7, wherein the first semiconductor chip is an uppermost semiconductor chip among the plurality of stacked semiconductor chips.

9. The semiconductor apparatus according to claim 7, wherein the second semiconductor chip is a lowermost semiconductor chip among the plurality of stacked semiconductor chips.

10. The semiconductor apparatus according to claim 7, wherein each of the plurality of stacked semiconductor chips comprises:
a charge unit configured to charge the plurality of through-silicon vias for the preset threshold time;
a test unit configured to compare the voltage levels of the plurality of through-silicon vias and the reference voltage level, and output a plurality of test result signals; and
a repair unit configured to repair a through-silicon via, which is in a fail state, according to the plurality of test result signals.

11. The semiconductor apparatus according to claim 10, wherein each of the plurality of stacked semiconductor chips further comprises:
a discharge unit configured to discharge the plurality of through-silicon vias.

12. The semiconductor apparatus according to claim 10, wherein the test unit comprises:
a plurality of test logics configured to compare a plurality of voltage signals, which are outputted from the plurality of through-silicon vias, with the reference voltage level, make pass/fail decisions with respect to the plurality of respective through-silicon vias, and output the plurality of test result signals.

13. The semiconductor apparatus according to claim 10, wherein the repair unit is configured to repair a through-silicon via, which is in a fail state, by outputting a signal selected between two adjacent through-silicon vias using the plurality of test result signals.

14. The semiconductor apparatus according to claim 10, wherein the repair unit comprises:
a plurality of flip-flops configured to store the plurality of test result signals;
a plurality of logic gates configured to perform a logical operation on previous repair signals. which are generated using the plurality of test result signals, and outputs of the plurality of flip-flops, and output the plurality of repair signals; and
a plurality of multiplexers each configured to select any one of two signals being outputted from two adjacent through-silicon vias according to a corresponding repair signal.

15. The semiconductor apparatus according to claim 7, wherein each of the plurality of stacked semiconductor chips further comprises:
a control signal generation unit configured to generate a plurality of control signals for controlling timing of the charge operation, the test operation and the repair operation.

16. The semiconductor apparatus according to claim 7, wherein each of the plurality of stacked semiconductor chips further comprises:
a control signal generation unit configured to generate a control signal for controlling timing of the charge operation, according to a first position signal which indicates an uppermost semiconductor chip among the plurality of stacked semiconductor chips, and generate control signals for controlling timing of the test operation and the repair operation, according to a second position signal which indicates a lowermost semiconductor chip among the plurality of stacked semiconductor chips.

17. The semiconductor apparatus according to claim 7, wherein each of the plurality of stacked semiconductor chips further comprises:
a control signal generation unit configured to generate a control signal for controlling timing of the charge operation, according to a first position signal which indicates an uppermost semiconductor chip among the plurality of stacked semiconductor chips, control a pulse width of the control signal for controlling the timing of the charge operation, according to a test mode signal, and generate control signals for controlling timing of the test operation and the repair operation, according to a second position signal which indicates a lowermost semiconductor chip among the plurality of stacked semiconductor chips.

18. A method for testing a semiconductor apparatus including a plurality of stacked semiconductor chips formed with a plurality of through-silicon vias, the method comprising:
charging the plurality of through-silicon vias for a preset threshold time by a first semiconductor chip among the plurality of stacked semiconductor chips so that pass-state through-silicon vias reaches a reference voltage level;
making pass/fail decisions with respect to the plurality of through-silicon vias by comparing voltage levels of the plurality of through-silicon vias and the reference voltage level by the first semiconductor chip among the plurality of stacked semiconductor chips; and
performing a repair operation for a through-silicon via, which is in a fail state, by a second semiconductor chip among the plurality of stacked semiconductor chips.

19. The method according to claim 18, wherein, before charging the plurality of through-silicon vias for the preset threshold time by the first semiconductor chip, the method further comprises:
discharging the plurality of through-silicon vias by the plurality of stacked semiconductor chips.

20. The method according to claim 18, wherein the first and second semiconductor chips among the plurality of stacked semiconductor chips are determined according to position signals which have information about positions of the plurality of stacked semiconductor chips.

21. The method according to claim 18, wherein the reference voltage level is the same as a power supply voltage which is used to charge the plurality of through-silicon vias.
